(19) United States
(12) Patent Application Publication
(10) Pub. No.: US 2024/0346208 A1
(43) Pub. Date: Oct. 17, 2024

(54) THERMAL HYDRAULIC EQUIPMENT DIGITAL TWIN FOR OPERATION OPTIMIZATION AND PREDICTIVE MAINTENANCE

(71) Applicants: Cesare Frepoli, Pittsburgh, PA (US); Michael G. Mankosa, Lancaster, PA (US)

(72) Inventors: Cesare Frepoli, Pittsburgh, PA (US); Michael G. Mankosa, Lancaster, PA (US)

(21) Appl. No.: 18/441,947

(22) Filed: Feb. 14, 2024

Related U.S. Application Data
(60) Provisional application No. 63/459,589, filed on Apr. 14, 2023.

(51) Int. Cl. G06F 30/23; G06F 30/17

(52) U.S. Cl. CPC G06F 30/23; G06F 30/17

(57) ABSTRACT

A thermal hydraulic equipment digital twin providing virtual asset modeling for a piece of thermal hydraulic equipment comprises a finite element based tribology tool receiving both real time sensor data of parameters of the thermal hydraulic equipment and historical sensor data of the thermal hydraulic equipment and providing tribology based virtual asset modeling for the piece of thermal hydraulic equipment; and a thermal hydraulic systems analysis tool receiving both real time sensor data of parameters of the thermal hydraulic equipment and historical sensor data of the thermal hydraulic equipment and providing thermal hydraulic virtual asset modeling for the piece of thermal hydraulic equipment; and wherein the thermal hydraulic equipment digital twin provides an assessment of the health of the piece of thermal hydraulic equipment.

### RELATED APPLICATIONS

This application claims priority to U.S. Patent Application Ser. No. 63/459,589, filed Apr. 14, 2023 titled “Thermal Hydraulic Equipment Digital Twin for Operation Optimization and Predictive Maintenance” which is incorporated herein by reference.

### STATEMENT REGARDING FEDERALLY SPONSORED RESEARCH OR DEVELOPMENT

This invention was made with government support under contract DE-SC0022703 awarded by Department of Energy (Agency Tracking Number 0000266701; Solicitation Topic Code C54 36c). The government has certain rights in the invention.

### BACKGROUND INFORMATION

### 1. Field of the Invention

The present invention relates to a digital twin for thermal hydraulic equipment and the use thereof in operational optimization and reliability engineering preventive maintenance, particularly in electrical power generation plants.

### 2. Background Information

The premise of predictive maintenance is that regular monitoring of the actual mechanical condition of assets, and operating efficiency of process systems will ensure the maximum interval between repairs; minimize the number and cost of unscheduled outages created by asset failures and improve the overall availability of operating plants. In this application the assets are generally thermal hydraulic equipment such as found in electrical power generation plants.

Including predictive maintenance in a total plant management program is long known to provide the ability to optimize the availability of process machinery and greatly reduce the cost of maintenance. Predictive maintenance is a condition-driven preventive maintenance program.

A 2001 study of 500 plants that implemented predictive maintenance methods indicated substantial improvements in reliability, availability and operating costs. Based on the study results, major improvements can be achieved in: maintenance costs, unscheduled machine failures, repair downtime, spare parts inventory, and both direct and in-direct overtime premiums. In addition, the study indicated a dramatic improvement in: machine life, production, operator safety, product quality and overall profitability. Based on the study, the actual costs normally associated with the maintenance operation were reduced by more than 50 percent. The addition of regular monitoring of the actual condition of process machinery and systems reduced the number of catastrophic, unexpected machine failures by an average of 55 percent. Projections of the study results indicate that reductions of 90 percent can be achieved using regular monitoring of the actual machine condition. Predictive maintenance was shown to reduce the actual time required to repair or rebuild plant equipment. The average improvement in mean-time-to-repair, MTTR, was a reduction of 60 percent. Prevention of catastrophic failures and early detection of incipient machine and systems problems increased the useful operating life of plant machinery by an average of 30 percent. A side benefit of predictive maintenance is the automatic ability to monitor the mean-time-between-failures, MTBF. This data can determine the most cost-effective time to replace machinery rather than continue to absorb high maintenance costs.

As noted above the present application is directed to maintaining thermal hydraulic equipment such as found in electrical power generation plants. An electrical generating power plant (also called a power station, a power plant, a generating station or a generating plant) is an industrial facility for the generation of electric power. Power stations are generally connected to an electrical grid. Many power stations contain one or more generators, namely a rotating machine that converts mechanical power into three-phase electric power. The relative motion between a magnetic field and a conductor creates an electric current. The energy source harnessed to turn the generator varies widely. Most power stations in the world burn fossil fuels such as coal, oil, and natural gas to generate electricity. Low-carbon power sources include nuclear power, and use of renewables such as solar, wind, geothermal, and hydroelectric.

One recent tool used for predictive maintenance or reliability predictive maintenance in electrical power generation plants is known as a digital twin. The digital twin in this context is considered as a tool that provides a virtual (or digital) simulation of a piece of equipment and compares the simulated conditions to reality, as provided by the equipment sensor data. The digital twin is an emerging and vital technology for digital transformation and intelligent upgrade. Driven by data and model, the digital twin can perform monitoring, simulation, prediction, optimization, and so on. Specifically, the digital twin modeling is the core for accurate portrayal of the physical entity, which enables the digital twin to deliver the functional services and satisfy the application requirements.

The 2022 book Artificial Neural Networks for Renewable Energy Systems and Real-World Applications presents current trends for the solution of complex engineering problems in the application, modeling, analysis, and optimization of different energy systems and manufacturing processes. Chapter 6 is “Digital twin predictive maintenance strategy based on machine learning improving facility management in built environment” and states that “Predictive maintenance . . . monitors the performance and condition of equipment during normal operation to reduce failure rates. This chapter deals with a predictive maintenance strategy to reduce mechanical and electrical plants malfunctioning for residential technical plant systems. The developed strategy can guarantee a tailored maintenance service based on machine learning systems, drastically reducing breakdowns after a maximum period of 3 years. The developed strategy evaluates an acceptable components failure rate based on statistical data and combining the average labor costs with the duration of each maintenance operation. The predictive strategies are elaborated on the minimum cost increase necessary to achieve the above mentioned objectives. A case study based on a 3-year period has been developed on a modern residential district in Rome comprised of 16 buildings and 911 apartments. In particular, the analysis has been performed considering mechanical, electrical, and lighting systems supplying the external and common areas, excluding the apartments to avoid data perturbation due to differenced users' behaviors. The overall benefits of predictive maintenance management through Big Data analysis have proven to substantially improve the overall operation of different plants such as mechanical and electrical plants of residential systems.”

In the article Digital Twin Model for Zero-Energy Districts: The Case Study of Anzio Port, Italy (Conference Paper—WIT Transactions on Ecology and the Environment Volume 260, Issue 2022, 19 Dec. 2022, Pages 357-363) states that a “digital twin (DT) for a built environment is able to predict performances and behaviors across the life cycle through the implementation of predictive models and the real-time monitoring systems. In the present paper, a DT application is described in order to transform port areas in zero-energy districts (ZED) in Italy. The project case study is the port of Anzio, as it is a particularly representative sample of a port in the Mediterranean Sea. The study focuses on energy management strategies for the existing structures integrated with production systems through renewable energy systems (RESs) for sustainable mobility. The energy analysis of the area highlights the potential of DT, combining building information modelling (BIM) and geographic information system (GIS) to evaluate different multi-scale scenarios maximizing benefits of energy efficiency strategies. The proposed DT framework of the Anzio port acquires energy data, presence data, projection of displacements and accesses, among others, together with the data acquired by the distributed sensors allowing elaborations, correlations, scenario simulations and providing insights through dashboards and data visualization.”

The overall benefits of digital twins in predictive maintenance management in electrical generation plants have proven to substantially improve the overall operation of such plants. The benefits derived from using such condition-based digital twins in predictive maintenance management in electrical generation plants have offset the capital equipment cost required to implement the program within the first few months. Use of predictive digital twin based maintenance techniques has further reduced the annual operating cost of predictive maintenance methods so that any plant can achieve cost-effective implementation of this type of maintenance management program.

The digital twin systems built to date have been rudimentary and have largely ignored physic based modelling of significant components of the plant assets, namely of the thermal hydraulic equipment of such plants. There is a need to improve the digital twin systems for thermal hydraulic equipment for use in operational optimization and predictive maintenance.

### SUMMARY OF THE INVENTION

One aspect of the present invention provides a thermal hydraulic equipment digital twin providing virtual asset modeling for a piece of thermal hydraulic equipment comprising a finite element based tribology tool receiving both real time sensor data of parameters of the thermal hydraulic equipment and historical sensor data of the thermal hydraulic equipment and providing tribology based virtual asset modeling for the piece of thermal hydraulic equipment; and a thermal hydraulic systems analysis tool receiving both real time sensor data of parameters of the thermal hydraulic equipment and historical sensor data of the thermal hydraulic equipment and providing thermal hydraulic virtual asset modeling for the piece of thermal hydraulic equipment; and wherein the thermal hydraulic equipment digital twin provides an assessment of the health of the piece of thermal hydraulic equipment.

The thermal hydraulic equipment digital twin according to one aspect of the present invention may provide wherein the finite element based tribology tool analyzes and simulates mechanical seals of the piece of thermal hydraulic equipment. The thermal hydraulic equipment digital twin according to the present invention may provide wherein the thermal hydraulic virtual asset modeling for the piece of thermal hydraulic equipment are based in part on conservation of energy; and wherein the thermal hydraulic virtual asset modeling for the piece of thermal hydraulic equipment includes heat transfer analysis for the piece of thermal hydraulic equipment in which the heat flow inside the thermal hydraulic equipment is modelled.

The thermal hydraulic equipment digital twin according to one aspect of the present invention may provide wherein the thermal hydraulic equipment digital twin is connected to a condition monitoring platform for the piece of thermal hydraulic equipment through an application program interface, and wherein the application program interface passes the real time sensor data of parameters of the thermal hydraulic equipment and the historical sensor data of the thermal hydraulic equipment to the digital twin for processing, and wherein the application program interface passes assessment of the health of the piece of thermal hydraulic equipment to the condition monitoring platform.

The thermal hydraulic equipment digital twin according to according to one aspect of the present invention provides wherein the digital twin is configured to forecast effects upon a safety analysis of record for the thermal hydraulic equipment. The thermal hydraulic equipment digital twin according to one aspect of the present invention provides wherein the digital twin is configured to calculate a predicted remaining useful life of the thermal hydraulic equipment.

The thermal hydraulic equipment digital twin according to one aspect of the present invention provides wherein the digital twin is configured to utilize machine learning based artificial intelligence systems with real time sensor data of parameters of the thermal hydraulic equipment and historical sensor data of the thermal hydraulic equipment. The digital twin may be configured to use machine learning techniques to compare historical signal data to live signal data to give information on component health.

The thermal hydraulic equipment digital twin according to one aspect of the invention may provide wherein the digital twin includes a mechanical analysis tool receiving both real time sensor data of parameters of the thermal hydraulic equipment and historical sensor data of the thermal hydraulic equipment and providing vibration analysis modeling of the thermal hydraulic equipment, finite element analysis modeling of the thermal hydraulic equipment, and stress/strain/wear analysis modeling of the thermal hydraulic equipment.

The thermal hydraulic equipment digital twin according to one aspect of the present invention may provide wherein the digital twin includes a motor current signature analysis tool configured to use motor controller current and voltage inputs of the thermal hydraulic equipment to assess electric motor health of the thermal hydraulic equipment.

The thermal hydraulic equipment digital twin according to one aspect of the present invention may provide wherein the digital twin provides a virtual sensor for the piece of thermal hydraulic equipment.

These and other advantages of the present invention will be clarified in the following description taken connection with the following figures in which like reference numbers represent like elements throughout.

### BRIEF DESCRIPTION OF THE DRAWINGS

FIG. 1 is a schematic view a digital twin for thermal hydraulic equipment and the implementation thereof in operational optimization and reliability engineering preventive maintenance in accordance with one embodiment of the present invention;

FIG. 2 is a schematic view a digital twin for thermal hydraulic equipment and the implementation thereof in operational optimization and reliability engineering preventive maintenance in accordance with another embodiment of the present invention.

### DESCRIPTION OF THE INVENTION

This following description outlines the technical aspect of a digital twin 100 for monitoring the health of industrial equipment and systems of assets 10, specifically thermal hydraulic (TH) equipment, for system optimization and predictive maintenance. The digital twin 100 and associated system of the invention includes the following attributes: Physics Driven: The system, specifically the digital twin 100 includes the application of multi-physics modeling of the asset 10; Data driven: the digital twin 100 can preferably implements Artificial Intelligence/Machine Learning (AI/ML) (190); Health Monitoring: Physics and data driven approaches used in the digital twin 100 and associated system of the invention will be combined to determine asset health 130; Automated Diagnostics: the digital twin 100 and associated system includes a determination of asset and component diagnostic issues; and Remaining Useful Life 194: the digital twin 100 and associated system yields a prediction of the time until asset 10 failure for predictive maintenance and/or asset replacement.

The digital twin 100 of the invention implements virtual asset modeling and simulation to inform and enhance the capabilities of plant operators to determine the health of plant assets 10 (specifically thermal hydraulic (TH) equipment 10) and associated plant systems incorporating TH equipment 10. The digital-twin 100 of the asset 10 is used to explain the correlation between the observed signals, behaviors and triggering events and alarms. The digital twin 100 of the asset 10, when referencing the present invention, is considered as a tool that provides a multi-physics based simulation of a piece of thermal hydraulic (TH) equipment 10 (asset) and compares the simulated conditions to reality, as provided by the equipment sensor data 14.

The digital twin 100 of the present invention is at a minimum i) a thermal hydraulics 120 and ii) tribology 110 digital twin. This base digital twin 100 can be expanded (via additional software ‘plug-ins’) to include additional physics packages.

The digital twin 100 of the present invention combines, at least, a tribology analysis tool 110, specifically a mechanical seal face analysis tool, and a thermal hydraulic systems analysis tool 120. The tribology analysis tool 110 may implement the mechanical face seal analysis found in the TRIBOS™ product from the applicant, Fpolisolutions. The mechanical seal face analysis tool 110 is a finite element based tribology tool used for analyzing mechanical seals.

Tribology is the science and engineering of interacting surfaces in relative motion. It includes the study and application of the principles of friction, lubrication and wear. Tribology is highly interdisciplinary, drawing on many academic fields, including physics, chemistry, materials science, mathematics, biology and engineering. The fundamental objects of study in tribology are tribosystems, which are physical systems of contacting surfaces. In lubricated tribosystems, contact stress can create tribofilms. Subfields of tribology include biotribology, nanotribology, space tribology and tribotronics. The importance of the field should not be overlooked, for example in 2017, Kenneth Holmberg and Ali Erdemir attempted to quantify the tribological impacts worldwide. They considered the four main energy consuming sectors: transport, manufacturing, power generation, and residential. The following were concluded: a) In total, ˜23% of the world's energy consumption originates from tribological contacts. Of that, 20% is to overcome friction and 3% to remanufacture worn parts and spare equipment due to wear and wear-related; B) By taking advantage of the new technologies for friction reduction and wear protection, energy losses due to friction and wear in vehicles, machinery and other equipment worldwide could be reduced by 40% in the long term (15 years) and 18% in the short term (8 years); C) On a global scale, these savings would amount to 1.4% of GDP annually and 8.7% of total energy consumption in the long term; D) the largest short term energy savings are envisioned in transport (25%) and in power generation (20%) while the potential savings in the manufacturing and residential sectors are estimated to be ˜10%. In the longer term, savings would be 55%, 40%, 25%, and 20%, respectively; and E) implementing advanced tribological technologies can also reduce global carbon dioxide emissions by as much as 1,460 million tons of carbon dioxide equivalent (MtCO₂) and result in $500,000,000,000 (450,000 million Euros) cost savings in the short term. In the long term, the reduction could be as large as 3,140 MtCO₂ and the cost savings $1,077,000,000,000 (970,000 million Euros). The system of the present invention will deliver on many of these identified advantages in the power generation sector.

The physics of tribology are known to tribologists, however the following is a brief overview of the implementation of the face seal analysis in the tribology analysis tool 110 of the digital twin 100 of the present invention.

Tribology begins with an understanding of friction. The word friction comes from the Latin “frictionem”, which means rubbing. This term is used to describe all those dissipative phenomena, capable of producing heat and of opposing the relative motion between two surfaces. There are two main types of friction: Static friction, which occurs between surfaces in a fixed state, or relatively stationary; and Dynamic friction, which occurs between surfaces in relative motion. The theories and studies on friction as implemented in the system of the invention can be simplified into three main laws, which are valid in most cases: First Law of Amontons—Friction is independent of the apparent area of contact; Second Law of Amontons—The frictional force is directly proportional to the normal load; and Third Law of Coulomb—Dynamic friction is independent of the relative sliding speed.

Tribology as implemented in the system tool 110 also considers that to reduce friction between surfaces and keep wear under control, materials called lubricants are used. Lubricants are not just oils or fats, but any fluid material that is characterized by viscosity, such as air and water. Of course, some lubricants are more suitable than others, depending on the type of use they are intended for: air and water, for example, are readily available, but the former can only be used under limited load and speed conditions, while the second can contribute to the wear of materials. These materials attempt to achieve a perfect fluid lubrication, or a lubrication such that it is possible to avoid direct contact between the surfaces in question, inserting a lubricant film between them. To do this there are two possibilities, depending on the type of application, the costs to address and the level of “perfection” of the lubrication desired to be achieved, there is a choice between: Fluidostatic lubrication (or hydrostatic in the case of mineral oils)—which consists in the insertion of lubricating material under pressure between the surfaces in contact; Fluid fluid lubrication (or hydrodynamics)—which consists in exploiting the relative motion between the surfaces to make the lubricating material penetrate.

The viscosity is the equivalent of friction in fluids, it describes, in fact, the ability of fluids to resist the forces that cause a change in shape. Temperature and pressure are two fundamental factors to evaluate when choosing a lubricant instead of another. Consider the effects of temperature initially. There are three main causes of temperature variation that can affect the behavior of the lubricant: ambient conditions; Local thermal factors (like for car engines or refrigeration pumps); and Energy dissipation due to rubbing between surfaces.

Tribology as implemented in the system tool 110 also considers the wear on the subject asset 10 component. The wear is the progressive involuntary removal of material from a surface in relative motion with another or with a fluid. Wear plays a fundamental role in tribological studies, and in the system of the invention, since it causes changes in the shape of the components used in the construction of machinery (for example). These worn parts must be replaced and this entails both a problem of an economic nature, due to the cost of replacement, and a functional problem, since if these components are not replaced in time, more serious damage could occur to the machine in its complex. There are different wear mechanisms the system tool 110 of the present invention can consider and account for, which may occur simultaneously or even combined with each other: Adhesive wear; Abrasive wear; Fatigue wear; Corrosive wear; Rubbing wear or fretting; Erosion wear; and Other minor wear phenomena (wear by impact, cavitation, wear-fusion, wear-spreading).

Regarding adhesive wear, as known, the contact between two surfaces occurs through the interaction between asperities. If a shearing force is applied in the contact area, it may be possible to detach a small part of the weaker material, due to its adhesion to the harder surface. The behavior of the adhesive wear volume can be described by means of three main laws: Law 1—Distance—The mass involved in wear is proportional to the distance traveled in the rubbing between the surfaces. Law 2—Load—The mass involved in wear is proportional to the applied load. Law 3—Hardness—The mass involved in wear is inversely proportional to the hardness of the less hard material.

The abrasive wear consists of the cutting effort of hard surfaces that act on softer surfaces and can be caused either by the roughness that as tips cut off the material against which they rub (two-body abrasive wear), or from particles of hard material that interpose between two surfaces in relative motion (three-body abrasive wear). At application levels, the two-body wear is easily eliminated by means of an adequate surface finish, while the three-body wear can bring serious problems and must therefore be removed as much as possible by means of suitable filters, even before of a weighted machine design.

The fatigue wear is a type of wear that is caused by alternative loads, which cause local contact forces repeated over time, which in turn lead to deterioration of the materials involved. This phenomenon can lead to the breaking of the surfaces due to mechanical or thermal causes. To reduce this type of wear, therefore, it is good to try to decrease both the contact forces and the thermal cycling, which is the frequency with which different temperatures intervene. For optimal results it is also good to eliminate, as much as possible, impurities between surfaces, local defects and inclusions of foreign materials in the bodies involved.

The corrosive wear occurs in the presence of metals that oxidize or corrode. When the pure metal surfaces come into contact with the surrounding environment, oxide films are created on their surfaces because of the contaminants present in the environment itself, such as water, oxygen or acids. These films are continually removed from the abrasive and adhesive wear mechanisms, continually recreated by pure-contaminating metal interactions. Clearly this type of wear can be reduced by trying to create an ‘ad hoc’ environment, free of pollutants and sensible to minimal thermal changes.

The rubbing wear occurs in systems subject to more or less intense vibrations, which cause relative movements between the surfaces in contact within the order of nanometers. These microscopic relative movements cause both adhesive wear, caused by the displacement itself, and abrasive wear, caused by the particles produced in the adhesive phase, which remain trapped between the surfaces. This type of wear can be accelerated by the presence of corrosive substances and the increase in temperature.

The erosion wear occurs when free particles, which can be either solid or liquid, hit a surface, causing abrasion. The mechanisms involved are of various kinds and depend on certain parameters, such as the impact angle, the particle size, the impact velocity and the material of which the particles are made up.

As detailed above the digital twin 100 implements a finite element based tribology tool 110 used for analyzing mechanical seals of the thermal hydraulic (TH) equipment 10 or asset.

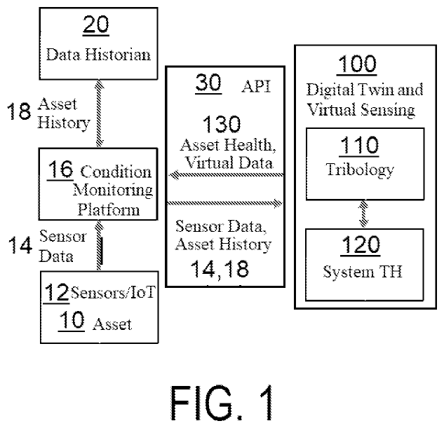

Additionally the digital twin 100 implements thermal-hydraulic analysis tool 120 of the thermal hydraulic (TH) equipment 10 (e.g. motor or pump or the like) which is used in the plant, namely the electrical power generation plant. A set of sensor parameter based mathematical models are developed for use in the thermal-hydraulic analysis tool 120 which are based on conservation of energy. Heat transfer analysis for the asset 10 is also implemented in the thermal-hydraulic analysis tool 120 in which the heat flow inside the asset 10 is described and modelled precisely. The theoretical basis and modeling strategy are applied in a typical thermal-hydraulic circuit of the asset 10. These, combined with additional encoded physics, can form the basis of the TH tool 120 of the digital twin 110. This concept is shown in FIG. 1.

FIG. 1 is a schematic view a digital twin 100 for thermal hydraulic equipment 10 and the implementation thereof in operational optimization and reliability engineering preventive maintenance in accordance with one embodiment of the present invention. FIG. 1 shows on the left the standard technology stack for a condition monitoring platform 16 comprising the asset 10 and plant sensors 12 and corresponding IoT (Internet of things) connections that transfer the sensor data 14 to the plant network and the historical database 20. The condition monitoring platform 16 utilizes the condition monitoring software which allows a user to view live asset sensor data 14. The historical database 20, also known as the data historian is for collecting and maintaining the asset data history 18.

The digital twin 100 of the invention is connected to the condition monitoring platform 16 through an API (Application program interface) 30, as shown in FIG. 1. The API 30 universally accepts all data types such that it can be connected to any condition monitoring platform 16 on the market. The API 30 passes sensor data 14 and asset history 18 to the digital twin 100 for processing. The API 30 will pass back virtual data and asset health 130 to the condition monitoring platform 16 for viewing and then to the data historian 20 for documenting.

The virtual data component of 130 may include ‘virtual sensors’ 140 where the digital twin 100 will calculate what a condition would be in a location of an asset 10 or the associated system that does not have a sensor directly measuring that quantity. The asset health component of 130 includes any component degradation, advanced calculation of operating states, and estimates of remaining useful life (194 discussed below).

The digital twin 100 shown in FIG. 1 can be described as formed of a “thermal hydraulic and tribology coupled physics solver” (FIG. 1 components 120 and 110, respectively). The physics modeling will take in sensor data 12 as boundary conditions and will solve for a steady state analysis. The digital twin 100 will assess component efficiency and generate a list of potential issues with the asset 10 or associated system ranked by probability.

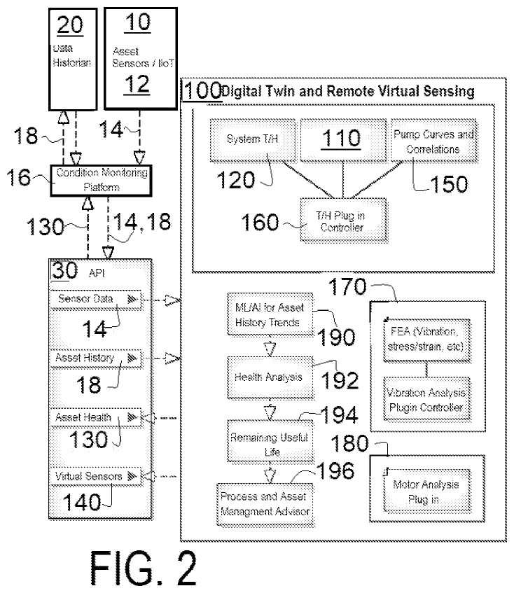

As shown in the embodiment of FIG. 2, additional features of the digital twin 100 may be added as “plug in” modules that perform added custom analysis such as vibration analysis in tool 170 and motor current signature analysis in tool 180. The system implements a multi-physics, multi-signal approach to the digital twin 100 by combining these individual plugins into a cohesive asset health assessment 130 and possibly virtual sensors 140. Plugins can be added based on available asset 10 sensor data 14.

FIG. 2 shows another option for the technology layout summary, and is a schematic view a digital twin 100 for thermal hydraulic equipment 10 and the implementation thereof in operational optimization and reliability engineering preventive maintenance in accordance with another embodiment of the present invention. In FIG. 2, digital twin 100 shows an expanded digital twin concept with the additional plugins over the twin shown in FIG. 1. In FIG. 2, an expanded thermal hydraulics plugin tool or controller 160 is the combination of a system thermal hydraulics analysis tool 120, tribology tool 110, and a pump curves and correlations analysis tool 150 which are coupled through the thermal hydraulics controller 160. In FIG. 2, the mechanical analysis plugin tool 170 includes vibration analysis, finite element analysis, and stress/strain/wear analysis. In FIG. 2, the motor current signature analysis plugin tool 180 uses motor controller current and voltage inputs to assess electric motor health of the asset 10.

The digital twin 100 of the invention has these plugins tools work together to provide insight into the health 130 of the individual system asset 10 and the system as a whole. To aid in this predictive maintenance, asset history 18 is used from the data historian 20.

The digital twin utilizes machine learning based artificial intelligence systems 190 with real time data 14 and historical data 18. Combining digital twin 100 analysis with asset history 18 and machine learning techniques is the basis for useable maintenance predictions. Essentially the system 190 uses machine learning techniques to compare historical signal data 18 to live signal data 14 wherein the twin 100 (via system 190) performs pattern recognition which is combined with the physics predictions to give information on component health (analysis step 192). This information will lead into additional logic for predicting the remaining useful life 194 of the asset 10 and will give the operator (via a process and asset manager advisor 196 and part of the asset health output) the ability to alter the simulated plant parameters in order to determine how to optimize asset life.

The invention uses an open architecture approach for the API 30 working with the digital twin 100, in order to not restrict its use to a single condition monitoring platform 16 and some commercial platforms 16 already have API hookups available.

This technology of the invention is particularly applicable to, or within the nuclear industry, which has unique regulatory requirements. A critical aspect for applying predictive tools in the nuclear industry is the demonstration and qualification of the credibility of such predictions. Especially when dealing with safety-related systems there are stringent requirements for quality control, traceability, explainability, scrutability and overall transparency. These principles are codified in the Regulatory Guide 1.203, the Evaluation Model Development and Assessment Process. These principles are followed when dealing with safety analyses of the invention and could provide a good basis for characterizing pedigree and confidence in the evaluation models considering within the digital-twin 100 and associated analytics.

The technology of the implementation of the digital twin 100 can be applied to current and future nuclear power plants as an online, real-time, operability assessment framework. By measuring the current state of the asset 10 (or collection of assets 10), the technology using the digital twin 100 will be able to forecast the implication or effect on the safety analysis of record (AOR). The AOR is how plant operators document and maintain the safety case for the operation of the plant. As the plant state changes over time, operability assessments are required to demonstrate the continued safe operation of the power plant. This technology will automate the process by reflecting the current state of the plant, and automatically feeding that information into an evaluation model that will monitor the safety analysis acceptance criteria.

The invention may implement a graphical user interface for the digital twin 100 software to allow for easier interaction with the twin 100. The GUI will allow the users to build models, make sensor connections, define analyses, and to perform post-processing.

In summary, the digital twin 100 of the system of the invention is the core for accurate portrayal of the physical entity, which enables the digital twin to deliver the functional services and satisfy the application requirements.

It will be apparent that various changes may be made to the present invention without departing from the spirit or scope thereof. The scope of the present invention is determined by the attached claims and equivalents thereto.

What is claimed is:

1. A thermal hydraulic equipment digital twin providing virtual asset modeling for a piece of thermal hydraulic equipment comprising:
a finite element based tribology tool receiving both real time sensor data of parameters of the thermal hydraulic equipment and historical sensor data of the thermal hydraulic equipment and providing tribology based virtual asset modeling for the piece of thermal hydraulic equipment; and
a thermal hydraulic systems analysis tool receiving both real time sensor data of parameters of the thermal hydraulic equipment and historical sensor data of the thermal hydraulic equipment and providing thermal hydraulic virtual asset modeling for the piece of thermal hydraulic equipment; and
wherein the thermal hydraulic equipment digital twin provides an assessment of the health of the piece of thermal hydraulic equipment.

2. The thermal hydraulic equipment digital twin according to claim 1, wherein the finite element based tribology tool analyzes and simulates mechanical seals of the piece of thermal hydraulic equipment.

3. The thermal hydraulic equipment digital twin according to claim 1 wherein the thermal hydraulic virtual asset modeling for the piece of thermal hydraulic equipment are based in part on conservation of energy.

4. The thermal hydraulic equipment digital twin according to claim 1, wherein the thermal hydraulic virtual asset modeling for the piece of thermal hydraulic equipment includes heat transfer analysis for the piece of thermal hydraulic equipment in which the heat flow inside the thermal hydraulic equipment is modelled.

5. The thermal hydraulic equipment digital twin according to claim 4 wherein the thermal hydraulic virtual asset modeling for the piece of thermal hydraulic equipment are based in part on conservation of energy.

6. The thermal hydraulic equipment digital twin according to claim 5, wherein the finite element based tribology tool analyzes and simulates mechanical seals of the piece of thermal hydraulic equipment.

7. The thermal hydraulic equipment digital twin according to claim 6, wherein the thermal hydraulic equipment digital twin is connected to a condition monitoring platform for the piece of thermal hydraulic equipment through an application program interface.

8. The thermal hydraulic equipment digital twin according to claim 7, wherein the application program interface passes the real time sensor data of parameters of the thermal hydraulic equipment and the historical sensor data of the thermal hydraulic equipment to the digital twin for processing.

9. The thermal hydraulic equipment digital twin according to claim 7, wherein the application program interface passes assessment of the health of the piece of thermal hydraulic equipment to the condition monitoring platform.

10. The thermal hydraulic equipment digital twin according to claim 7, wherein the digital twin is configured to forecast effects upon a safety analysis of record for the thermal hydraulic equipment.

11. The thermal hydraulic equipment digital twin according to claim 7, wherein the digital twin is configured to calculate a predicted remaining useful life of the thermal hydraulic equipment.

12. The thermal hydraulic equipment digital twin according to claim 7, wherein the digital twin is configured to utilize machine learning based artificial intelligence systems with real time sensor data of parameters of the thermal hydraulic equipment and historical sensor data of the thermal hydraulic equipment.

13. The thermal hydraulic equipment digital twin according to claim 12, wherein the digital twin is configured to use machine learning techniques to compare historical signal data to live signal data to give information on component health.

14. The thermal hydraulic equipment digital twin according to claim 7, wherein the digital twin includes a mechanical analysis tool receiving both real time sensor data of parameters of the thermal hydraulic equipment and historical sensor data of the thermal hydraulic equipment and providing vibration analysis modeling of the thermal hydraulic equipment, finite element analysis modeling of the thermal hydraulic equipment, and stress/strain/wear analysis modeling of the thermal hydraulic equipment.

15. The thermal hydraulic equipment digital twin according to claim 7, wherein the digital twin includes a motor current signature analysis tool configured to use motor controller current and voltage inputs of the thermal hydraulic equipment to assess electric motor health of the thermal hydraulic equipment.

16. The thermal hydraulic equipment digital twin according to claim 1, wherein the digital twin provides a virtual sensor for the piece of thermal hydraulic equipment.

17. A thermal hydraulic equipment digital twin providing virtual asset modeling for a piece of thermal hydraulic equipment of an electrical power generation plant comprising:
a finite element based tribology tool receiving real time sensor data of parameters of the thermal hydraulic equipment and providing tribology based virtual asset modeling for the piece of thermal hydraulic equipment; and
a thermal hydraulic systems analysis tool receiving real time sensor data of parameters of the thermal hydraulic equipment and providing thermal hydraulic virtual asset modeling for the piece of thermal hydraulic equipment; and
wherein the thermal hydraulic equipment digital twin provides an assessment of the health of the piece of thermal hydraulic equipment for monitoring the health of the piece of thermal hydraulic equipment for system optimization and predictive maintenance.

18. The thermal hydraulic equipment digital twin according to claim 16, wherein the digital twin implements virtual asset modeling and simulation to inform and enhance the capabilities of plant operators to determine the health of the thermal hydraulic equipment and associated plant systems incorporating the thermal hydraulic equipment.

19. The thermal hydraulic equipment digital twin according to claim 16, wherein the digital twin provides a virtual sensor for the piece of thermal hydraulic equipment.

20. The thermal hydraulic equipment digital twin according to claim 16, wherein the digital twin provides correlation between the observed signals, behaviors and triggering events and alarms.
